(19) United States
(12) Patent Application Publication
(10) Pub. No.: US 2007/0090516 A1
(43) Pub. Date: Apr. 26, 2007

(54) Heated substrate support and method of fabricating same

(75) Inventor: John M. White, Hayward, CA (US)

Correspondence Address: PATTERSON & SHERIDAN, LLP, 3040 POST OAK BOULEVARD, SUITE 1500, HOUSTON, TX, 77056, US

(73) Assignee: Applied Materials, Inc.

(21) Appl. No.: 11/341,297

(22) Filed: Jan. 27, 2006

Related U.S. Application Data
(60) Provisional application No. 60/727,930, filed on Oct. 18, 2005.

(51) Int. Cl. H01L 23/12

(52) U.S. Cl. 257/704

(57) ABSTRACT

A method and apparatus for forming a substrate support is provided herein. In one embodiment, the substrate support is fabricated by a process that includes forming a groove in a body, disposing a heater element in the groove, and welding the groove to enclose the heater element, wherein the welding forces at least a portion of the body into intimate contact with the heater element. In another embodiment, a method of forming a substrate support is provided that includes forming a groove in a body, disposing a heater element in the groove and stir welding the groove closed to encase the heater element.

### CROSS-REFERENCE TO RELATED APPLICATION

This application claims benefit of U.S. Patent Application Ser. No. 60/727,930, filed Oct. 18, 2005, which is herein incorporated by reference in its entirety.

This application is also related to U.S. patent application Ser. No. 10/965,601, filed Oct. 13, 2004 and to U.S. patent application Ser. No. 11/115,575, filed Apr. 26, 2005, which are herein incorporated by reference in there entireties.

### BACKGROUND OF THE INVENTION

1. Field of the Invention

Embodiments of the invention generally provide a substrate support utilized in substrate processing and a method of fabricating the same.

2. Description of the Related Art

Liquid crystal displays or flat panels are commonly used for active matrix displays such as computer and television monitors. Generally, flat panels comprise two glass plates having a layer of liquid crystal material sandwiched therebetween. At least one of the glass plates includes at least one conductive film disposed thereon that is coupled to a power supply. Power supplied to the conductive film from the power supply changes the orientation of the crystal material, creating a pattern such as text or graphics that can be seen on the display. One fabrication process frequently used to produce flat panels is plasma enhanced chemical vapor deposition (PECVD).

Plasma enhanced chemical vapor deposition is generally employed to deposit thin films on a substrate such as a silicon or quartz wafer, large area glass or polymer workpiece, and the like. Plasma enhanced chemical vapor deposition is generally accomplished by introducing a precursor gas into a vacuum chamber that contains the substrate. The precursor gas is typically directed through a distribution plate situated near the top of the chamber. The precursor gas in the chamber is energized (e.g., excited) into a plasma by applying RF power to the chamber from one or more RF sources coupled to the chamber. The excited gas reacts to form a layer of material on a surface of the substrate that is positioned on a temperature controlled substrate support. In applications where the substrate receives a layer of low temperature polysilicon, the substrate support may be heated in excess of 400 degrees Celsius. Volatile by-products produced during the reaction are pumped from the chamber through an exhaust system.

Generally, the substrate support utilized to process flat panel displays are large, most often exceeding 550 mm×650 mm. The substrate supports for high temperature use are typically forged or welded, encapsulating one or more heater elements and thermocouples in an aluminum body. The substrate supports typically operate at elevated temperatures (i.e., in excess of 350 degrees Celsius and approaching 500 degrees Celsius). Due to these high operating temperatures, the heater elements encapsulated in the substrate supports are susceptible to failure due to local hot spots that may form if the heat is not properly carried away and distributed throughout the substrate support.

Although substrate supports configured in this manner have demonstrated good processing performance, manufacturing such supports has proven difficult and expensive. Moreover, as the cost of materials and manufacturing the substrate support is great, failure of the substrate support is highly undesirable. Additionally, if the substrate support fails during processing, a substrate supported thereon may be damaged. As this may occur after a substantial number of processing steps have been preformed thereon, the resulting loss of the in-process substrate may be very expensive. Furthermore, replacing a damaged support in the process chamber creates a costly loss of substrate throughput while the process chamber is idled during replacement or repair of the substrate support. Moreover, as the size of the next generation substrate supports are increased to accommodate substrates in excess of 2 square meters at operating temperatures approaching 500 degrees Celsius, the aforementioned problems become increasingly more important to resolve.

Therefore, there is a need for an improved substrate support.

### SUMMARY OF THE INVENTION

A method and apparatus for forming a substrate support is provided herein. In one embodiment, the substrate support is fabricated by a process that includes forming a groove in a body, disposing a heater element in the groove, and welding the groove to enclose the heater element, wherein the welding forces at least a portion of the body into intimate contact with the, heater, element. In another embodiment, a method of forming a substrate support is provided that includes forming a groove in a body, disposing a heater element in the groove and stir welding the groove closed to encase the heater element.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic sectional view of one embodiment of a processing chamber having a substrate support of the present invention;

FIG. 2 is a partial cross-sectional view of one embodiment of the substrate support assembly of FIG. 1;

FIGS. 3 and 5-7 are partial cross-sectional and bottom views of a substrate support assembly illustrating different stages of fabrication;

FIG. 4 is an elevation of one embodiment of a tool suitable for use in the fabrication sequence described with reference to the FIGS. 3 and 5-7;

FIGS. 8-9 are partial cross-sectional and bottom views of another substrate support assembly illustrating different stages of fabrication;

FIGS. 10-12 are bottom and partial sectional views of another substrate support in different stages of fabrication;

FIG. 13 is a top plan view of another embodiment of a substrate support assembly;

FIG. 14 is a partial cross-sectional view of another embodiment of the substrate support assembly;

FIG. 15 is a partial cross-sectional view of the substrate support assembly of FIG. 14 prior to welding;

FIG. 16 is a partial cross-sectional view of the stem to body interface of the substrate support assembly of FIG. 14;

FIG. 17 is a partial cross-sectional view of another embodiment of the substrate support assembly;

FIG. 18 is a partial cross-sectional view of the substrate support assembly of FIG. 17 prior to welding;

FIG. 19 is a is a partial cross-sectional view of another embodiment of the substrate support assembly; and

FIG. 20 is a schematic sectional view of another embodiment of a processing chamber having heating and/or cooling features embedded using the method of present invention.

To facilitate understanding, identical reference numerals have been used, wherever possible, to designate identical elements that are common to the figures. It is contemplated that features and elements of one embodiment may be beneficially incorporated in other embodiments without further recitation.

### DETAILED DESCRIPTION

The invention generally provides a heated substrate support and methods of fabricating the same. The invention is illustratively described below in reference to a PECVD system, such as a PECVD system available from AKT, a division of Applied Materials, Inc., located in Santa Clara, Calif. However, it should be understood that the invention has utility in other system configurations such as physical vapor deposition systems, ion implant systems, etch systems, other chemical vapor deposition systems and other systems in which use of a heated substrate support is desired.

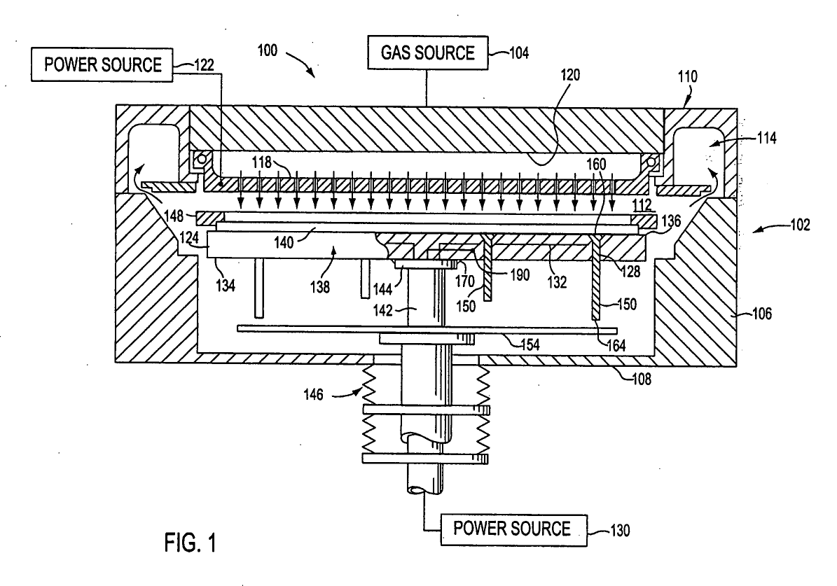

FIG. 1 is a cross sectional view of one embodiment of a plasma enhanced chemical vapor deposition system 100. The system 100 generally includes a chamber body 102 coupled to a gas source 104. The chamber body 102 has walls 106, a bottom 108, and a lid assembly 110 that define a chamber volume 112. The chamber volume 112 is typically accessed through a port (not shown) in the walls 106 that facilitates movement of the substrate 140 into and out of the chamber body 102. The walls 106 and bottom 108 are typically fabricated from a unitary block of aluminum or other material compatible for processing. The lid assembly 110 contains a pumping plenum 114 that couples the chamber volume 112 to an exhaust port (that includes various pumping components, not shown).

The lid assembly 110 is supported by the walls 106 and can be removed to service the chamber body 102. The lid assembly 110 is generally comprised of aluminum. A distribution plate 118 is coupled to an interior side 120 of the lid assembly 110. The distribution plate 118 is typically fabricated from aluminum. The center section includes a perforated area through which process and other gases supplied from the gas source 104 are delivered to the chamber volume 112. The perforated area of the distribution plate 118 is configured to provide uniform distribution of gases passing through the distribution plate 118 into the chamber body 102.

A heated substrate support assembly 138 is centrally disposed within the chamber body 102. The support assembly 138 supports a substrate 140 during processing. The substrate may be a silicon, glass, plastic or other workpiece, for example, those substrates suitable for manufacturing flat panel displays, OLEDs, solar panels and the like. In one embodiment, the substrate support assembly 138 comprises an aluminum body 124 that encapsulates at least one embedded heater element 132 and a thermocouple 190. The body 124 may optionally be coated or anodized. Alteratively, the body 124 may be made from other weldable materials compatible with the processing environment, and may also be comprised one or more sections. It is recognized that encapsulating the heater element 132 in a one-piece body 124 will provide advantages in ease of fabrication, enhance temperature uniformity and heater performance.

The heater element 132, such as an electrode disposed in the support assembly 138, is coupled to a power source 130 and controllably heats the support assembly 138 and substrate 140 positioned thereon to a predetermined temperature. Typically, the heater element 132 maintains the substrate 140 at a uniform temperature of from about 150 to at least about 460 degrees Celsius. Although one heater element 132 is shown, it is contemplated that multiple heater elements may be utilized and independently controlled to provide zones of temperature control. It is also contemplated that the heater element 132 may be a fluid conduit adapted to flow a heat transfer fluid therethrough, among other temperature control devices.

Generally, the support assembly 138 has a lower surface 134 and an upper surface 136. The upper surface 136 is configured to support the substrate during processing. In one embodiment, the upper surface 136 is configured to support a substrate greater than or equal to about 550 by about 650 millimeters. In one embodiment, the upper surface 136 has a plan area greater than or equal to about 0.35 square meters for supporting substrates having a size greater than or equal to about 550 by 650 millimeters. In one embodiment, the upper surface 136 has a plan area of greater than or equal to about 2.7 square meters (for supporting substrates having a size greater than or equal to about 1500 by 1800 millimeters). The upper surface 136 may generally have any shape or configuration. In one embodiment, the upper surface 136 has a substantially polygonal shape. In one embodiment, the upper support surface is a quadrilateral.

The lower surface 134 has a stem cover 144 coupled thereto. The stem cover 144 generally is an aluminum ring sealably coupled to the support assembly 138 that provides a mounting surface for the attachment of a stem 142 thereto. The stem 142 is sealingly coupled the stem cover 144 at an upper end and is coupled at a lower end to a lift system (not shown) that moves the support assembly 138 between an elevated position (as shown) and a lowered position. A bellows 146 provides a vacuum seal between the chamber volume 112 and the atmosphere outside the chamber body 102 while facilitating the movement of the support assembly 138. The stem 142 additionally provides a conduit for electrical and thermocouple leads between the support assembly 138 and other components of the system 100. To provide a pressure barrier between the interior passages of the stem 142 and the chamber volume 112 of the chamber body 102, the stem 142 is continuously welded to the stem cover 144. Likewise, the stem cover 144 is sealed to the lower surface 134 of the body 124 by a continuous weld 170.

The support assembly 138 has a plurality of holes 128 disposed therethrough that accept a plurality of lift pins 150. The lift pins 150 are typically comprised of ceramic or anodized aluminum. Generally, the lift pins 150 have first ends 160 that are substantially flush, with or slightly recessed from an lower surface 134 of the support assembly 138 when the lift pins 150 are in a normal position (i.e., retracted relative to the support assembly 138). The first ends 160 are generally flared to prevent the lift pins 150 from falling through the holes 128. A second end 164 of the lift pins 150 extends beyond the lower side 126 of the support assembly 138. The lift pins 150 may be displaced relative to the support assembly 138 by a lift plate 154 to project from the support surface 134, thereby placing the substrate in a spaced-apart relation to the support assembly 138.

The support assembly 138 generally is grounded such that RF power supplied by a power source 122 to the distribution plate 118 (or other electrode positioned within or near the lid assembly of the chamber) may excite the gases disposed in the chamber volume 112 between the support assembly 138 and the distribution plate 118. The RF power from the power source 122 is generally selected commensurate with the size of the substrate to drive the chemical vapor deposition process.

The support assembly 138 additionally supports a circumscribing shadow frame 148. Generally, the shadow frame 148 prevents deposition at the edge of the substrate 140 and support assembly 138 so that the substrate does not stick to the support assembly 138.

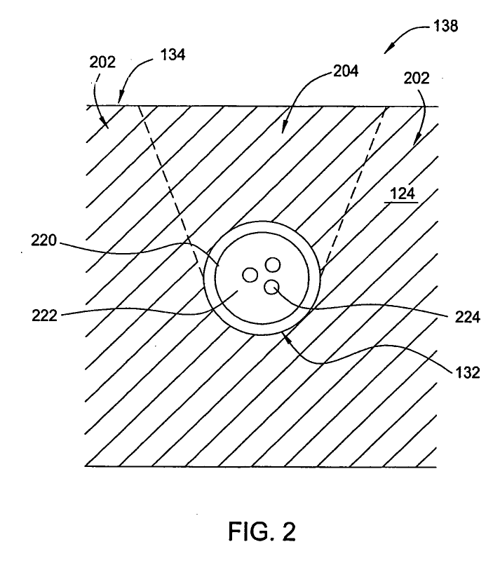

FIG. 2 depicts a partial cross-sectional view of the heater element 132 disposed in the body 124 of the substrate support assembly 138. The heater element 132 generally includes a plurality of conductive elements 224 encased in a dielectric 222 and covered with a protective sheath 220. The heater element 132 may optionally include a cladding which surrounds the sheath 220. The cladding forms an integral bond with the sheath 220, having substantially no air pockets trapped between the cladding and the sheath 220. In one embodiment, the heater element 132 may be clad by tightly wrapping a conformable sheet of the cladding around the sheath 220.

Generally, the cladding has good thermal conductivity and is thick enough to be a heat sink at high heating rates to substantially prevent hot spots on the heater element 132 during operation. As such, the cladding generally may comprise any material with high thermal conductivity such that the cladding is a sink for the heat produced by the conductive elements 224 during operation. The cladding is also generally softer, or more malleable, than the body 124 of the substrate support assembly 138. In one embodiment, the cladding may be made from a high purity, super plastic aluminum material, such as aluminum 1100 up to about aluminum 3000-100 series. In another embodiment, the cladding may be made from any 1XXX series of materials that easily accepts cold or hot working, where X is an integer. The cladding may be fully annealed. In one embodiment, the cladding is formed from aluminum 1100-0. In another embodiment, the cladding is formed from aluminum 3004.

The heater element 132 is encased in the body 124 using a process that urges the material of the body 124 into intimate contact with the heater element 132. In the embodiment depicted in FIG. 2, the heater element 132 is encased in the body 124 using a friction stir welding process.

As shown in FIG. 2, a weld effected region 204 is disposed above the heater element 132. A non-effected region 202 is laterally offset from the weld effected region 204, and also is in contact with a portion of the heater element 132. During the welding process that encases the heater element 132 in the body 124, the weld effected region 204 becomes subject to plastic deformation, and under the pressure of the weld, is forced toward and makes intimate contact with the heater element 132. The extruded weld effected region 204 places the body 124 and heater element 132 in good thermal contact, for example, greater than about 75 percent.

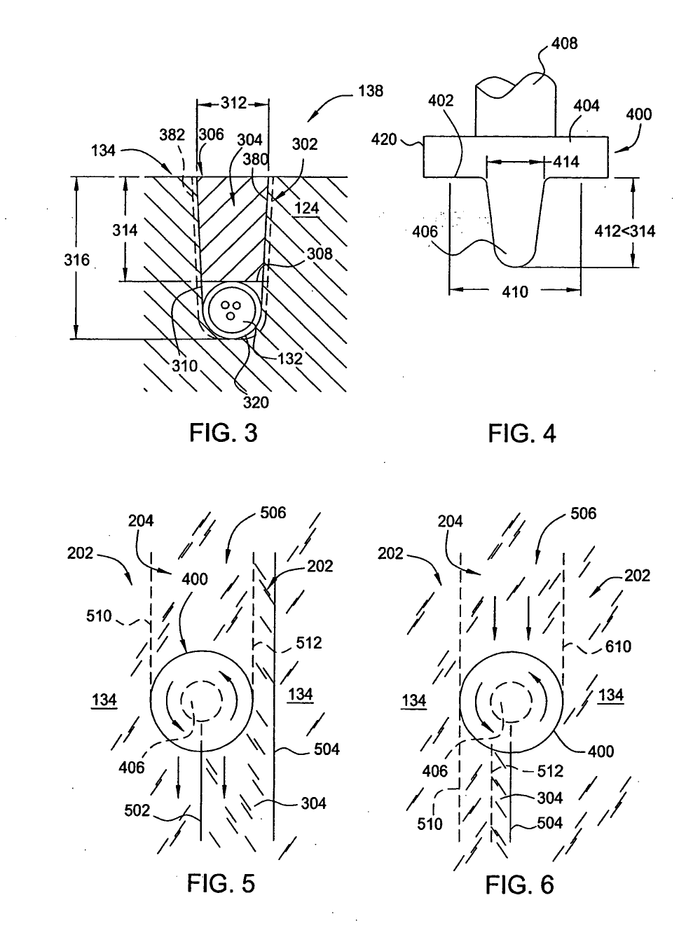

FIGS. 3 and 5-7 depict partial sectional and top view of the body 124 illustrating one embodiment of a fabrication sequence for embedding the heater 132. FIG. 4 depicts one embodiment of a tool 400 suitable for stir welding the body 124 during the fabrication sequence of illustrated by FIGS. 3 and 5-7.

Referring first to FIG. 3, a groove 302 is formed in the bottom surface 134 of the substrate support assembly 138 to accept the heater element 132. A depth 316 of the groove 302 may be selected to position the heater element 132 at a predefined location in the body 124. In one embodiment, the depth 316 is equal to or slightly greater than half the thickness of the body 124.

A width 312 of the groove 302 may be selected to create a press-fit with the heater element 132 and the walls 380 of the groove on insertion into the groove. Alternatively, the width 312 may be selected to provide clearance between the walls of the groove 302 (walls 382 are shown in phantom) and the heater element 132, thereby allowing the heater element 132 to be freely disposed on a bottom 320 of the groove 302.

The walls of the groove 302 may be substantially straight and parallel, or optionally formed at a slight angle or taper, such that the bottom 320 of the groove 302 is slightly narrower than the top portion of the groove 302 defined at the bottom surface 134. The angle of taper of the groove 302 is generally less than 3 degrees, although larger taper angles are also contemplated. In one embodiment, the sidewalls of the groove 302 are tapered such that the bottom of the groove has approximately the same width as the diameter of the heater element 132. Thus, the heater element 132 may be forced into and become engaged with the groove 302 to prevent the heater element 132 from “popping” out of the groove prior to installation of the cap 304.

The bottom 320 of the groove 302 may be radiused to conform with the shape of the heater element 132. Alternatively, or in combination, the bottom 320 of the groove 302 may be roughened, or textured.

The cap 304 is disposed in the groove 302 and covers the heater element 132. The cap 304 has an outer surface 306 that is disposed substantially flush with the lower surface 134 of the substrate support assembly 138. The cap 304 is may be press fit, or have a small clearance with the walls of the groove 302. The cap 304 is formed from a material suitable for welding to the body 124, and in one embodiment, is aluminum.

Referring now to the elevation of the tool 400 depicted in FIG. 4, the tool 400 has a disc-shaped body 404 and a probe 406 extending from one side and a shaft 408 extending from the opposite side of the tool 400. The shaft 408 facilitates coupling the tool 400 to an actuator (not shown) that controls the rotation, down-force and lateral motion to the tool 400. The tool 400 is fabricated from a wear resistance material suitable for stir welding the body 124 and cap 304.

The body 404 may have a diameter 410 such that an outer edge 420 of the body 404 is equal to or greater than about the width 312 of the groove 302. A shoulder 402 of the body 404 has sufficient surface area to heat the body 124 and cap 304 of the substrate support assembly 138 when rotated thereagainst during the stir welding process.

The probe 406 may have a diameter 414 that is equal to or greater than about half the width 312 of the groove 302. It is also contemplated that the diameter 414 may be less than about half the width 312 of the groove 302. The probe 406 has a length 412 that is slightly less than a depth 314 of the cap 304, as seen in the side-by-side arrangement of FIGS. 3 and 4. The length 412 of the probe 406 is selected to cause the plasticized portions of the body 124 and/or cap 304, created during welding, to be extruded or otherwise forced towards the heater element 132, thereby filling the pre-weld voids 310 present between the heater element 132 and cap 304, and thereby creating an intimate heat transfer contact surface between the heater element 132 and the body 124.

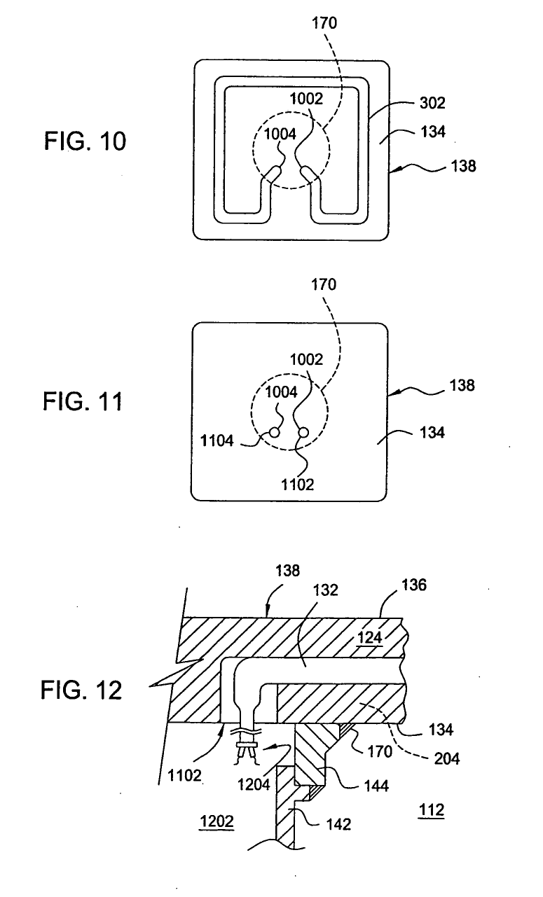

FIGS. 5 and 6 depict the path of the tool 400 over the body 124 during the welding process. Referring first to FIG. 5, the tool 400 is disposed against the body 124 such that the shoulder 402 of the tool 400 is in contact with the bottom surface 134 of the body 124. The probe 406 is penetrated into the groove 302. To accommodate entry and exit of the probe 406 into the groove 302, the cap 304 may end short of the lateral end of groove 302, which will become apparent in the discussion of FIGS. 10-11 below.

As the tool 400 spins and advances along a first interface 502 between the body 124 and cap 304, the advancing probe 406 plasticizes adjacent regions of the body 124 and cap 304, forming a solid phase bond 506 between the body 124 and cap 304 along the trailing edge of the probe 406. The solid phase bond 506 created by this stir welding technique is defined by a first outer weld line 510 defined between the body 124 and the solid phase bond 506 and an interim weld line 512 defined between the cap 304 and the solid phase bond 506 by the outer edge 420 of the tool 400. A second interface 504 between the body 124 and cap 304 remains unwelded during the first pass of the tool 400.

Referring now to FIG. 6, the second interface 504 between the body 124 and cap 304 is welded in a manner similar to the welding of the first interface 502. The probe 406 is rotated and advanced along the second interface 504. The probe 406 plasticizes the adjacent regions of the cap 304 and the solid phase bond 506 created during the first pass of the tool 400 described with reference to FIG. 5. The solid phase bond 506 is expanded along the trailing edge of the probe 406 such that the residual portion of the cap 304 remaining after the first pass is consumed during the welding of the second interface 504, becoming an integral part of the body 124. The expanded solid phase bond 506 fuses the body 124 on opposing sides of the groove 302, thereby encapsulating the heater element 132 in the body 124. The solid phase bond 506 created by the stir welding technique is now defined by the first outer weld line 510 defined between the body 124 and the solid phase bond 506 and a second outer weld line defined between the body 124 and the solid phase bond 506 by the outer edge 420 of the tool 400.

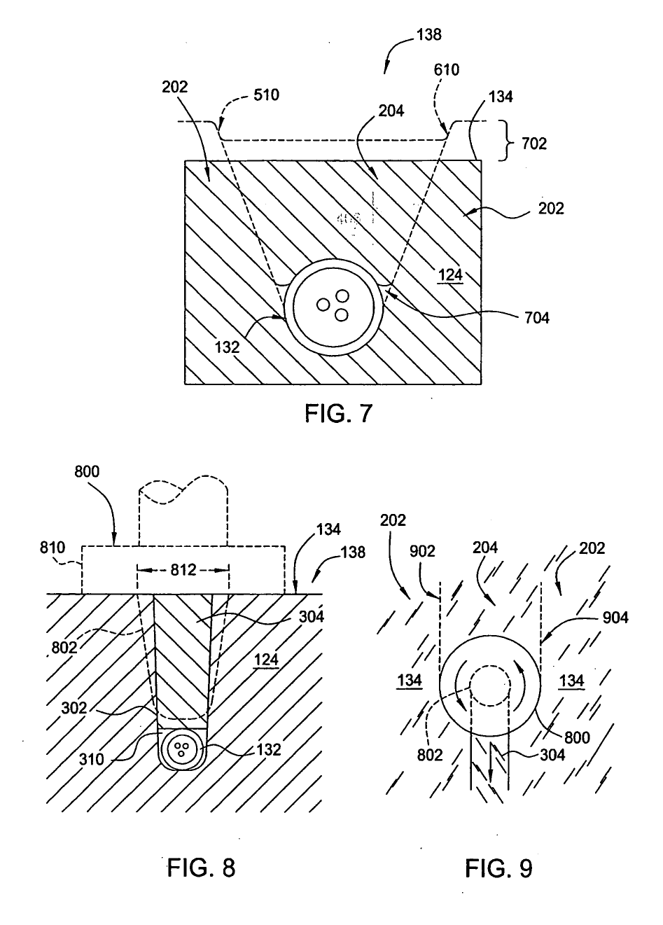

During the passes of the tool 400 along the interfaces 502, 504 between the body 124 and cap 304, the plasticized material from the body 124 and/or the cap 304 is retained substantially in the groove 302 by the shoulder 420 of the tool 400. The plasticized material is forced towards the heater element 132, thereby substantially filling the voids 310 present prior to welding, as shown in FIG. 7. A portion of the voids 310 may remain unfilled after processing, leaving an air pocket 704 proximate the heater element 132. The air pocket 704 is usually small or non-existent. In one embodiment, at least 25 percent of the circumference of the heater element 124 is in contact with the body 124. In other embodiment, at least 50 percent of the circumference of the heater element 124 is in contact with the body 124. In other embodiment, at least 25 percent of the circumference of the heater element 124 is in contact with the body 124. In still another embodiment, the circumference of the heater element 124 is completely contacting the body 124.

The tool 400 may form a shallow trench in the body 124 during the welding operations. To elimination the trench, a portion 702 of the lower surface 134 of the body 124 may be machined (i.e., removed) after welding to return the lower surface 134 to a substantially planar condition. The substrate support assembly 138 may also be machined on the upper side 136 to balance the heat distribution from the embedded heater element 132.

FIG. 8 is a partial sectional view of another embodiment of tool 800 for encapsulating the heater element 132 in the body 124 of the substrate support assembly 138. Tool 800 is substantially similar to the tool 400 described above, except that a probe 802 extending from a body 810 of the tool 800 has a diameter 812 slightly greater than the width 312 of the groove 302. The wider probe 802 allows the probe 802 to integrate the material of the cap 304 into the body 124 using a single pass of the probe 800, as shown in FIG. 9. The cap 304 is consumed and incorporated into the body 124 as a continuous solid phase bond 506 defined by the weld lines 902, 904 separating the non-effected regions 202 from the weld effected regions 204 of the body 124.

FIGS. 10-11 are bottom views of the body 124. The groove 302 may be formed in the bottom surface 134 of the body 124 in a predefined configuration arranged to provide a desired heat distribution. Ends 1002, 1004 of the groove 302 are located inside the location of the weld 170 (shown in phantom) used to secure the cover plate to the 144 to the body 124 after installation of the heater element 124. In embodiments where multiple heater elements 132 are utilized, more than one groove 302 may be formed in the body 124 with ends thereof located inside the weld 170, as described above.

Holes 1102, 1104 are formed by the welding process at the ends of 1002, 1004 of the groove 302. Referring additionally to FIG. 12, the holes 1102, 1104, which permit engagement of the probe with the support assembly 138, facilitate the routing of heater leads 1204 into a conduit 1204 defined through the stem 142. As the holes 1102, 1104 are positioned inside the weld 170, the solid phase bond 506 covering the portion of the heater element 132 outside of the cover plate 144 provides a pressure barrier between the chamber volume 112 of the chamber body 102 and the environment shared by the heater element 132 and conduit 1204.

It is contemplated that the groove 302 may be formed in the upper surface 136 of the support assembly, wherein the through holes 1102, 1104 are provided to allow access of the leads 1204 to the conduit 1202 defined by the stem 142. In such an embodiment, a plug is conventionally welded to seal the portion of the holes 1102, 1104 provided on the upper surface 136 to accommodate the probe of the stir welding tool.

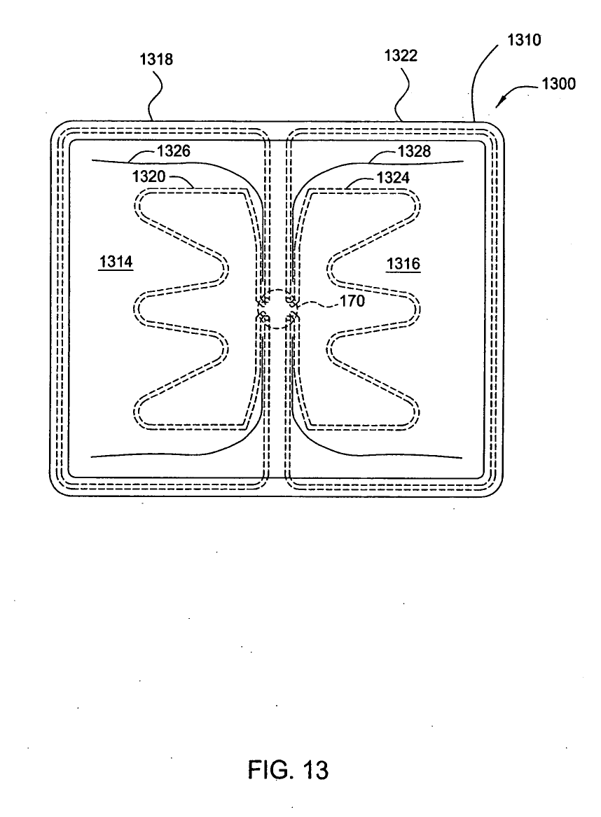

FIG. 13 is a top plan view of one embodiment of a substrate support assembly 1300 having multiple, illustratively shown heater elements as two heater elements 1302, 1304 in broken lines.

A body 1310 of the support assembly 1300 includes an upper surface 132 that is divided into a plurality of thermal control zones, shown illustratively as two control zones 1314, 136.A first outer zone heater element 1318 is embedded within a periphery of the first zone 1314 of the body 1310. A first inner zone heater element 1320 is embedded within an area bounded by the first outer zone heater element 1318. A second outer zone heater element 1322 is embedded within a periphery of the second zone 1316. A second inner zone heater element 1324 is embedded within an area bounded by the second outer zone heater element 1322.

A first outer thermocouple 1326 is embedded within the body 1310 and between the first outer zone heater element 1318 and the first inner zone heater element 1320 for controlling temperature of the first zone 1314. In addition, a second outer thermocouple is embedded within the body 1310 and extends between the second outer zone heater element 1322 and the second inner zone heater element 1324 for controlling temperature of the second zone 1316.

Leads for the heater elements 1318, 1320, 1322, 1324 and the thermocouples 1326, 1324 may be routed into the shaft 142 of the substrate support assembly 1300 as illustrated in FIG. 12. Additionally, the temperature of the heater elements 1318, 1320, 1322, 1324 may be individually controlled, such that the temperature profile of the body in the substrate position thereon may be regulated.

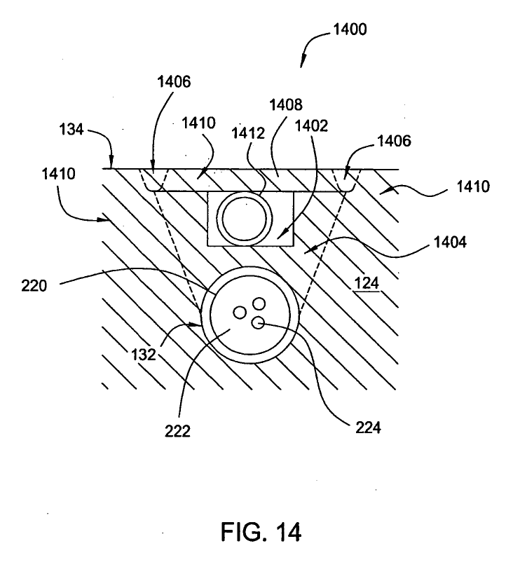

FIG. 14 is a partial sectional view another embodiment of a substrate support assembly 1400 having at least one cooling passage 1402. The substrate support assembly 1400 is generally similar to the substrate support assemblies described above, with a heater element 132 stir-welded in a body 124 of the substrate support assembly 1400.

The cooling passage 1402 is generally formed in the body 124 between the heater element 132 and the lower-surface 134 of the body 124. The cooling passage 1402 is coupled to a coolant fluid source (not shown) which provides a heat transfer fluid (such as water, among others) that is circulated through the cooling passage 1402 to assist in regulating the temperature of the support assembly 1400.

In one embodiment, the heat transfer fluid is circulated in a tube 1412 disposed in the cooling passage 1402. Alternatively, the heat transfer fluid may be circulated directly in contact with the body 124 defining the cooling passage 1402. The cooling passage 1402 may be larger than the tube 1412 such that the tube 1412 makes intermittent contact with the body 124 (as shown in FIG. 16). Alternatively, the tube 1412 may be tightly disposed in the passage 1402 or compressed against the body 124. The tube 1412 may be fabricated from a material having good heat conduction, suitable for use at operating temperatures of the support assembly 132, and compatible with the heat transfer fluid. One example of a suitable material for the tube 1412 is stainless steel.

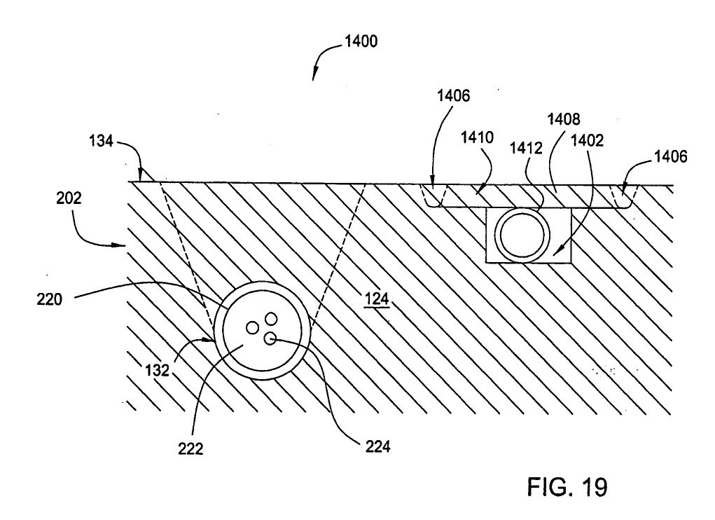

In the embodiment depicted in FIG. 14, the body 124 includes a non-effected region 1410 and a weld-effected region 1404 generated while embedding the heater element 132. The cooling passage 1402 may be positioned between the heater element 132 and the upper surface 134 of the body 124, and in the embodiment depicted in FIG. 14, the cooling passage 1402 and tube 1412 are disposed in the weld-effected region 1404. The cooling passage 1402 may alternatively be offset from the weld-effected region 1404, as shown in FIG. 19.

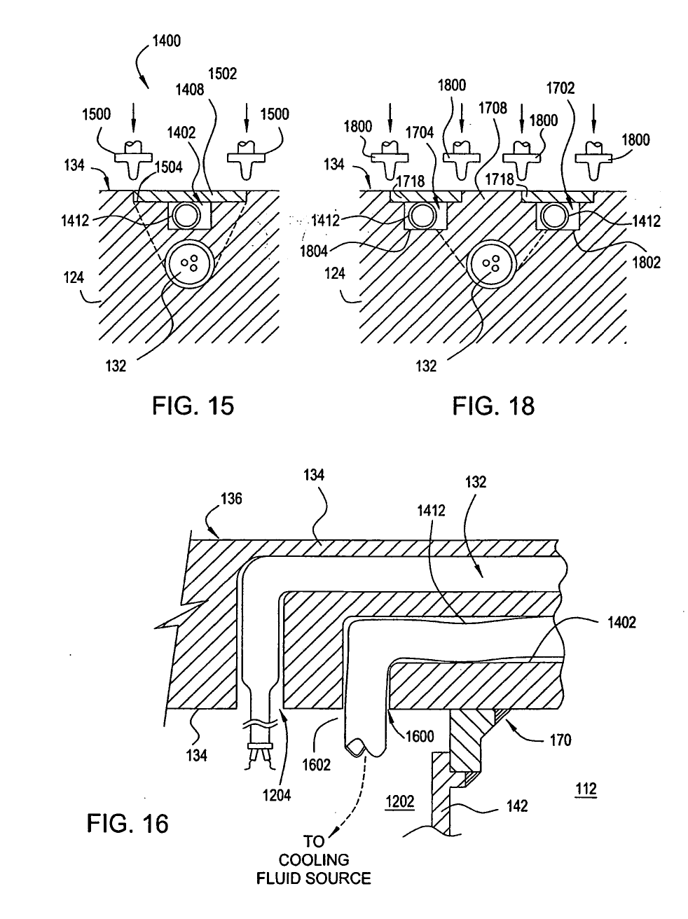

Referring additionally to FIG. 15, a lower boundary of the cooling passage 1402 is formed by a channel 1502 formed in the weld-effected region. An upper boundary of the cooling passage 1402 is formed by a cap plate 1408 that is positioned in the channel 1502 and welded to the upper surface 134. In one embodiment, the channel 1502 includes a step 1504 that supports the cap plate 1408 in a predefined position to set the sectional area of the cooling passage 1402. The cap plate 1408 is continuously welded to seal the channel 1502, for example, by electron beam or other weld methodology suitable for forming a continuous seal.

In the embodiment depicted in FIG. 15, a stir welding tool 1500 is utilized to stir weld the cap plate 1408 to the body 124. The tool 1500 is configured to generate a small weld-effected zone 1406 that is offset from the channel 1502 to minimize the possibility of material, extruded during the welding process, from entering the passage 1402.

FIG. 16 is a partial sectional view of the support assembly 1400 illustrating an inlet port 1600 of the cooling passage 1402. The port 1600 is positioned inside the weld 170, thereby allowing the tube 1412 (or conduit coupled thereto) to be routed through the stem 142 to a cooling fluid source (not shown) while maintaining isolation from the environment inside the processing chamber. The port 1600 is generally formed at the exit location of the tool 1500. The port 1600 may be formed in the tool exit hole, or the tool exit hole may be sealingly plugged before forming the port 1600.

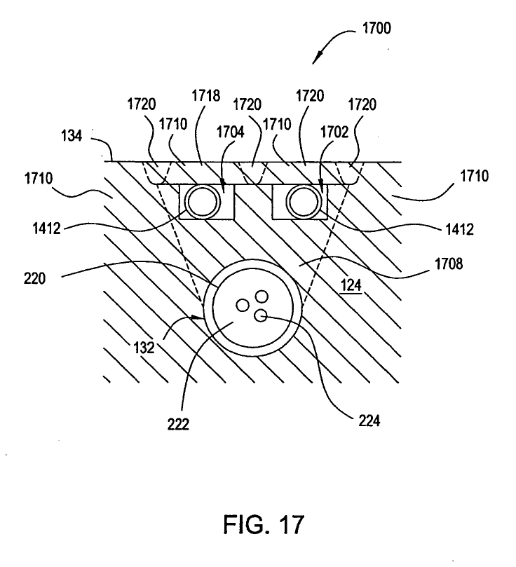

FIG. 17 is a partial sectional view another embodiment of a substrate support assembly 1700 having at least two cooling passages 1702, 1704. The substrate support assembly 1700 is generally similar to the substrate support assemblies described above, with a heater element 132 stir-welded in a body 124 of the substrate support assembly 1700. In the embodiment depicted in FIG. 17, a respective tube 1412 is deposed in each cooling passage 1702, 1704.

The cooling passages 1702, 1704 are generally formed in the body 124 between the heater element 132 and the lower surface 134 of the body 124. The tubes 1412 disposed in the cooling passages 1702, 1704 are coupled to a coolant fluid source (not shown) which provides a heat transfer fluid that is circulated through the passages. The tubes 1412 in the cooling passages 1702, 1704 may be coupled to the coolant fluid source in a manner that provides the fluid of the same temperature through the passages, or the temperature of the fluid in each tube 1412 disposed in the cooling passages 1702, 1704 may be independently controlled. The cooling passages 1702, 1704 may arranged in an offset orientation, or may be routed thought different portions of the body 124 such that cooling may be independently controlled in different lateral zones. For example, the first passage 1702 may be predominantly routed and/or located in the central region of the body 124 while the second passage 1704 may be predominantly routed and/or located in the outer regions/perimeter of the body 124 (i.e., the first passage 1702 is disposed inward of the second passage 1704). The flow direction of fluid through the cooling passages 1702, 1704 may be in the same or opposing directions.

In the embodiment depicted in FIG. 17, the body 124 includes a non-effected region 1710 and a weld-effected region 1708 generated while embedding the heater element 132. The cooling passages 1702, 1704 and tubes 1412 may be positioned between the heater element 132 and the upper surface 134 of the body 124, and in the embodiment depicted in FIG. 17, the cooling passages 1702, 1704 are disposed at least partially in the weld-effected region 1708. An upper boundary of each of the cooling passages 1702, 1704 is formed by at least one cap plate 1718. The cooling passages 1702, 1704 may be bounded by a single or separate cap plates 1718.

Referring additionally to FIG. 18, a lower boundary of the cooling passages 1702, 1704 are formed by channels 1802, 1804 formed in the weld-effected region 1708. The cap plates 1718 are positioned in the channels 1802, 1804 and are welded to the upper surface 134 as described above. In one embodiment, each channel 1802, 1804 includes a step 1806 that supports the cap plates 1718 in a predefined position.

In the embodiment depicted in FIG. 18, a stir welding tool 1800 is utilized to stir weld the cap plates 1718 to the body 124. The tool 1800 is configured to generate a small weld-effected zone 1720 that is offset from the channels 1802 1804 to minimize the possibility of material, extruded during the welding process, from entering the passages 1702, 1704. The ports (not shown) of the passages 1702, 1704 are positioned inside the weld 170, as described with reference to FIG. 16.

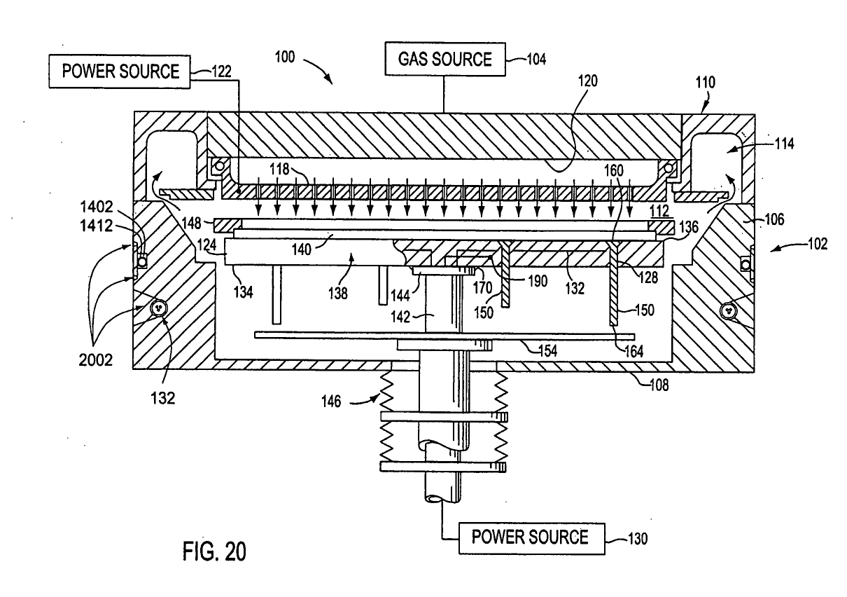

It is additionally contemplated that heating and/or cooling features may be embedded using the stir welding techniques described above in other components of a processing system. For example, in the embodiment of the system 100 depicted in FIG. 20, at least one of a heater element 132 and/or a cooling passage 1402 is embedded in a component thereof, such as a chamber body 102 and/or lid 110, and/or other component. A tube 1412 may be disposed in the passage 1402. A weld effected region 2002 effectively embeds the heater element 132 and/or seals cooling passage 1402 as discussed above.

Thus, a substrate support assembly has been provided that has an embedded heater element that is in intimate contact with the base material comprising the body of the substrate support. Advantageously, the process provides a pressure barrier while extruding the base material into contact with the heater, thereby filling voids that contribute to non-uniformity and heater burn-out. Moreover, the heater element embedding process allows for the substrate support assembly to be fabricated from a single plate (e.g., body) which is advantageous over multi-plate susceptors/heaters for ease of fabrication, heater location control and low cost. Moreover, the embedding technique may be advantageously utilized to efficiently embed heater and/or cooling elements in other portions of a processing system.

While the foregoing is directed to embodiments of the present invention, other and further embodiments of the invention may be devised without departing from the basic scope thereof, and the scope thereof is determined by the claims that follow.

What is claimed is:

1. A substrate support assembly fabricated by a method comprising:
forming a groove in a body;
disposing a heater element in the groove; and
welding the groove to enclose the heater element, wherein the welding further comprises forcing at least a portion of the body into intimate contact with the heater element.

2. The substrate support assembly of claim 1, wherein welding further comprises:
welding a cap to walls of the groove to the body in at least one tool pass.

3. The substrate support assembly of claim 1 further comprising:
disposing a cap in the groove.

4. The substrate support assembly of claim 3, wherein welding further comprises:
plasticizing the cap and the body to form a single solid phase bond enclosing the heater element in the body.

5. The substrate support assembly of claim 3, wherein welding further comprises:
bonding the cap to opposite walls of the groove in a single tool pass.

6. The substrate support assembly of claim 1, wherein welding further comprises:
plasticizing at least a portion of the body; and
forcing the plasticized portion of the body into contact with the heater element.

7. The substrate support assembly of claim 1 further comprising:
forming a pressure barrier outward of holes formed by the welding.

8. The substrate support assembly of claim 7, wherein forming the pressure barrier further comprises.
circumscribing the holes with a continuous weld coupling a stem cover to the body.

9. The substrate support assembly of claim 1, wherein the body is comprised of a single plate having an upper substrate supporting surface.

10. The substrate support assembly of claim 1 further comprising:
at least one cooling channel formed in the body.

11. The substrate support assembly of claim 10, wherein the cooling channel is formed in a weld effected region of the body.

12. The substrate support assembly of claim 10 further comprising:
a tube disposed in the cooling channel.

13. The substrate support assembly of claim 1 further comprising:
a first cooling channel formed in the body; and
a second cooling channel formed in the body inward of the first cooling channel.

14. A substrate support assembly comprising:
a body having a substrate support surface; and
a heater element embedded in the body by stir welding, wherein at least a portion of the body plasticized during stir welding is forced into intimate contact with the heater element.

15. The substrate support assembly of claim 14 further comprising:
a cap welded over the heater element to the body.

16. The substrate support assembly of claim 14 further comprising:
a cap consumed during the embedding of the heater element within the body.

17. The substrate support, assembly of claim 16, wherein an area of the body over the heater element further comprises:
cap and body material mixed together.

18. The substrate support assembly of claim 14 further comprising:
at least one cooling channel formed in the body.

19. The substrate support assembly of claim 18, wherein the cooling channel is formed in a weld effected region of the body.

20. The substrate support assembly of claim 18 further comprising:
a tube disposed in the cooling channel.

21. A method of embedding a heater in a body, comprising:
forming a groove in a body;
disposing a heater element in the groove; and
welding the groove to enclose the heater element, wherein the welding further comprises forcing at least a portion of the body into intimate contact with the heater element.

22. The method of claim 21, wherein welding further comprises:
welding a cap walls of the groove to the body in at least one tool pass.

23. The method of claim 21 further comprising:
disposing a cap in the groove.

24. The method of claim 23, wherein welding further comprises:
plasticizing the cap and the body to form a single solid phase bond enclosing the heater element in the body.

25. The method of claim 23, wherein welding further comprises:
bonding the cap to opposite walls of the groove in a single tool pass.

26. The method of claim 21, wherein welding further comprises:
plasticizing at least a portion of the body; and
forcing the plasticized portion of the body into contact with the heater element.

27. The method of claim 21 further comprising:
forming a pressure barrier outward of holes formed by the welding.

28. The method of claim 27, wherein forming the pressure barrier further comprises.
circumscribing the holes with a continuous weld coupling a stem cover to the body.

29. The method of claim 27, wherein the body is comprised of a single plate having an upper substrate supporting surface.

30. The method of claim 21 further comprising:
forming a cooling passage in a weld effected region located between the heater element and the upper surface of the body.

31. The method of claim 30 further comprising:
enclosing a tube in the cooling channel.

32. The method of claim 21, wherein the body is a substrate support suitable for supporting a substrate in a vacuum processing system.

33. The method of claim 21, wherein the body is a lid of a vacuum processing chamber.

34. The method of claim 21, wherein the body at least partially encloses a processing volume of a vacuum processing chamber.

35. A method of forming a substrate support, comprising:
forming a groove in a body;
disposing a heater element in the groove; and
stir welding the groove closed to substantially encase the heater element.

36. The method of claim 35 further comprising:
forming a cooling passage in a weld effected region of the body contacting the heater element.

37. The method of claim 36 further comprising:
enclosing a tube in the cooling channel.
